(19) United States
(12) Patent Application Publication
(10) Pub. No.: US 2026/0052970 A1
(43) Pub. Date: Feb. 19, 2026

(54) USE BACK SIDE POWER VIAS FOR SIGNALS

(71) Applicant: Applied Materials, Inc., Santa Clara, CA (US)

(72) Inventors: Martinus Maria BERKENS, Waalre (NL); Simon Johannes KLAVER, Weert (NL)

(73) Assignee: Applied Materials, Inc., Santa Clara, CA (US)

(21) Appl. No.: 18/803,153

(22) Filed: Aug. 13, 2024

(51) Int. Cl. H01L 23/522; H01L 21/768; H01L 29/06; H01L 29/417; H01L 29/66

(52) U.S. Cl. CPC H01L 23/5226; H01L 21/76879; H10D 62/113; H10D 64/017; H10D 64/254

(57) ABSTRACT

A semiconductor device may include a substrate. The semiconductor device may include a backside metal layer disposed on a backside of the substrate and may include a first track and a second track. The semiconductor device may include a device layer may include a dummy source, a dummy gate, an active source, and an active gate. The semiconductor device may include a frontside metal pathway electrically connecting the dummy gate and the active gate. The device may include a first metal through substrate via (TSV) connecting the first track and the active source. The device may include a second metal TSV connecting the second track and the dummy source.

### TECHNICAL FIELD

The present technology relates to semiconductor systems, processes, and equipment. More specifically, the present technology relates to backside power delivery networks.

### BACKGROUND

Modern semiconductor devices have grown smaller while adding components, leading to complex routing solutions for both data and power networks. The competition for space between metal pathways to transmit both power and data signals has led to some power deliver networks to be provided on a backside of the semiconductor devices. At the same time, certain data signals may be important to many components within the semiconductor devices. While backside power deliver networks may reduce the competition for space on the frontside of semiconductor devices, greater efficiency in routing both power and data signals within semiconductor devices is desired.

### BRIEF SUMMARY

A semiconductor device (“device”) may include a backside power delivery network (BPDN) formed on a backside of a substrate. The BPDN may include power signals and a data signal. The semiconductor device may include a device layer overlaying the BPDN. The device layer may include a device with a gate. The semiconductor device may include a frontside metal layer overlaying the device layer, where the data signal in the BPDN is conductively connected to the gate through the metal layer through one or more vias extending through the device layer.

In some embodiments, the semiconductor device may include a dummy gate formed in the device layer and configured to isolate the data signal of the BPDN. The data signal of the BPDN may be connected to a source/drain formed in the device layer and the source/drain may be connected to the gate via the metal layer. The data signal may be conductively connected to a plurality of gates of the device layer via the metal layer, characterized by a run distance of 10 to 20 microns, inclusive. The power signal and the data signal may be provided on a single track. The power signal and the data signal may be provided on separate tracks. The data signal may include a clock signal and/or a reset signal.

A method of forming a semiconductor device may include forming a first metal layer on a back side of a substrate, the substrate including one or more cavities extending from a front side of the substrate to the back side of the substrate. The method may include forming one or more metal vias within the one or more cavities. The method may include forming a device layer including at least a gate and a source/drain, where the source/drain is in contact with at least one of the metal vias. The method may include forming a second metal layer connecting the source/drain to the gate.

In some embodiments, the first metal layer and at least one of the one or more metal vias are a backside power delivery network (BPDN). The at least one metal via connected to the source/drain may be configured to provide a data signal from at least one of the first metal layer to the second metal layer or the second metal layer to the first metal layer. The method may include forming one or more dummy gates such that the metal via connected to the source/drain is isolated. The first metal layer may include a single track configured to provide power signals and data signals. The first metal layer is formed using a chemical vapor deposition process. The device layer may include a high drive cell including one or more gates conductively connected in parallel. A first portion of the one or more metal vias are power vias and a second portion of the one or more metal vias may be data vias, and the first portion and the second portion may be formed by a single process. The data vias may form a portion of a route with a length between 10 and 20 microns, inclusive. The first metal layer is formed on a first track for providing power signals and a second track for providing data signals.

A semiconductor device may include a substrate. The semiconductor device may include a backside metal layer disposed on a backside of the substrate and may include a first track and a second track. The semiconductor device may include a device layer may include a dummy source, a dummy gate, an active source, and an active gate. The semiconductor device may include a frontside metal pathway electrically connecting the dummy gate and the active gate. The device may include a first metal through substrate via (TSV) connecting the first track and the active source. The device may include a second metal TSV connecting the second track and the dummy source.

In some embodiments, the second track, the second metal TSV, and the frontside metal pathway may form a backside data channel. The first track and the first metal TSV may form a power delivery network.

### BRIEF DESCRIPTION OF THE DRAWINGS

FIG. 1 illustrates a top plan view of one embodiment of a processing system of deposition, etching, baking, and curing chambers that may be included or configured according to certain embodiments.

FIG. 2 illustrates a flowchart of a method for manufacturing a semiconductor device with a backside via for data signals, according to certain embodiments.

FIG. 3 illustrates a semiconductor device, according to certain embodiments.

FIG. 4A illustrates a top-down view of a semiconductor device with a backside signal channel, according to certain embodiments.

FIG. 4B illustrates a top-down view of a semiconductor device with a backside signal channel, according to certain embodiments.

FIG. 4C illustrates a top-down view of a semiconductor device, according to certain embodiments.

### DETAILED DESCRIPTION

Modern semiconductor devices include multiple devices disposed in one or more layers of the semiconductor device. These devices may all be connected to one or more networks of metal lines or vias to transmit power and data signals to and from the various devices. As the semiconductor devices have become more complex, the networks have also become more complex, creating issues with routing, signal integrity, and other such issues. As both power signals and data signals are fundamentally electrical current provided via metal pathways, one may interfere with the other.

In a typical semiconductor device, a device layer (or layers) may be disposed on a substrate layer (e.g., a silicon wafer). A metal layer of various pathways and vias may then be disposed on the device layer(s) (e.g., on the frontside of the semiconductor device). Some of the various pathways and vias may be used to provide power to the devices within the device layers, and others may be used to transmit data to and from the various devices of the device layer(s). As the number of device layers (and devices) increases, the space needed to route power signals through a power delivery network (PDN) and the space needed to route the data signals compete with one another. Furthermore, the resistivity (especially that of the PDN) increases and can make the power delivered to each of the devices less reliable.

To address these issues, the PDN may be disposed on the backside of the semiconductor device. A metal layer may be connected from the backside of the substrate to some or all of the devices in the device layer(s) by through substrate vias (TSVs). The data network, by contrast, may still be disposed on (or over) the device layer (i.e., the frontside). Thus, the PDN may be routed to the devices of the device layer(s) without competing for space with the data network, allowing for more reliable transmission of power and/or data signals and allowing the semiconductor device to be manufactured smaller and/or more complex (e.g., with more devices). However, in typical backside signal delivery, the data signals may be provided with backside metal to frontside metal vias. Connecting these vias directly to the frontside metal (e.g., the data network) may cause issues with signal integrity as well as complicate manufacturing processes. For example, instead of creating vias as in a typical PDN, the backside to frontside metal vias may also need to be created (e.g., in a different step, using different processes, etc.).

Because the PDN is routed such that robust pathways and vias are provided to each (or at least of) the devices of the device layer, the PDN may also provide an opportunity to deliver certain signals to the device layer without the use of backside to frontside metal vias. For example, for all the devices to operate within the semiconductor device, a shared clock signal may be provided to each device such that the various operations of the devices may be orchestrated properly. The clock signal, therefore, may be routed via the backside PDN to the device layer(s). Adding a TSV for each device to deliver the clock signal may be inefficient from a manufacturing and structural standpoint.

One solution may be to create a dedicated channel on the backside PDN for signal delivery. A backside metal layer with one or more channels may be formed on a backside of a substrate. One or more cavities may extend through from a frontside of the substrate to the backside of the substrate. The cavities may then be filled with a metal to form TSVs, where the backside metal and the TSVs form a backside PDN. At least some of the channels of the backside PDN may be configured to deliver power to devices in a device layer. Other channels (signal channel) may be configured to provide a signal to the device layer. Instead of connecting the signal channel directly to a device (e.g., a source/drain of a MOSFET), the signal channel (i.e., a TSV connected thereto) may be connected to a dummy source and isolated by dummy gates. Then, a topside metal layer may be connected to the dummy source and one or more devices in the device layer. The backside PDN may therefore be utilized to deliver signals (such as a clock signal) to multiple devices without competing for space with other portions of the data network and without providing vias to each of the devices.

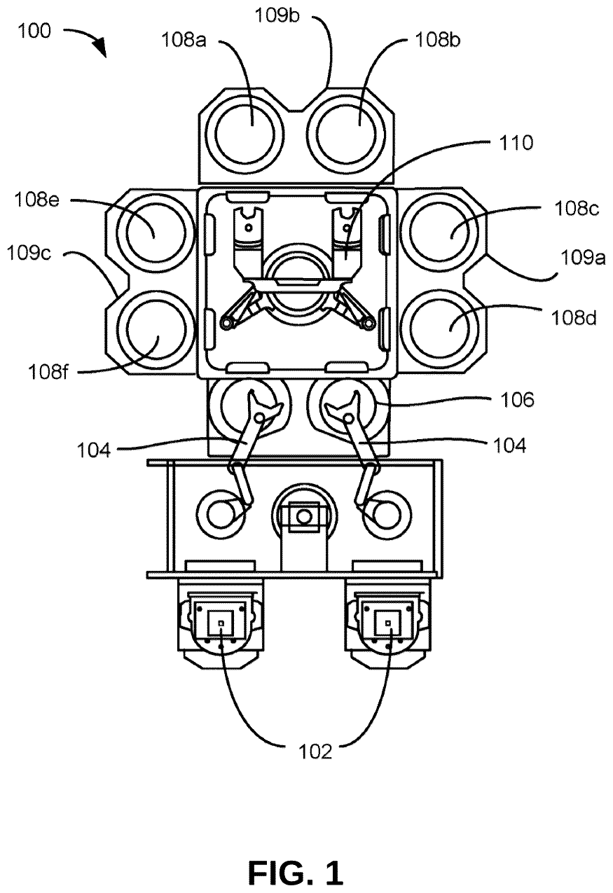

FIG. 1 illustrates a top plan view of one embodiment of a processing system 100 of deposition, etching, baking, and curing chambers that may be included or configured according to certain embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108c-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

System 100, or more specifically chambers incorporated into system 100 or other processing systems, may be used to produce structures according to some embodiments of the present technology.

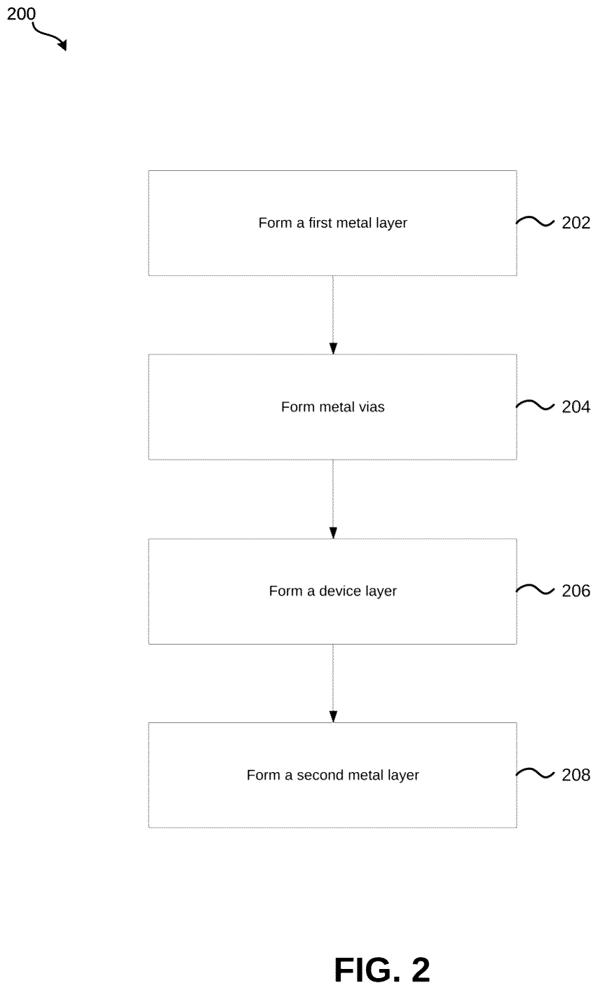

FIG. 2 illustrates a flowchart of a method 200 for manufacturing a semiconductor device with a backside via for data signals, according to certain embodiments. The method 200 may be performed by some or all of the system 100, described in relation to FIG. 1. Some steps of the method 200 may be performed in an order different than that described herein and or be combined with other steps. In some embodiments, some steps may be skipped altogether.

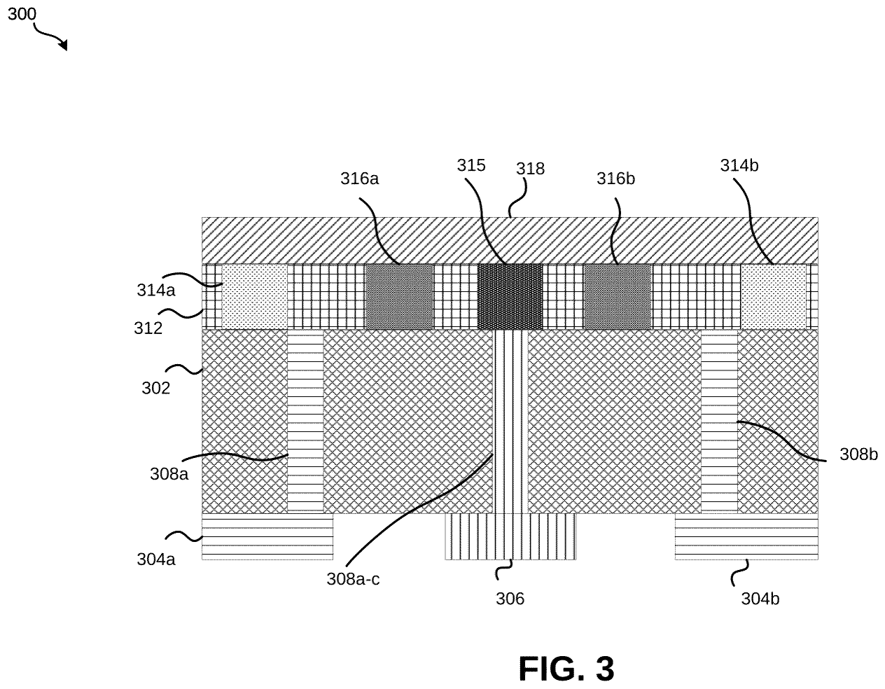

FIG. 3 illustrates a semiconductor device 300 including through substrate vias 308a-c, according to certain embodiments. The semiconductor device (“device”) 300 may be, manufactured using the method 200, and will be described in relation to the method 200.

At step 202, the method 200 may include forming a first metal layer on a back side of a substrate, the substrate comprising a one or more cavities extending from a front side of the substrate to the back side of the substrate. Turning to FIG. 3, the first metal layer may form a first backside metal 304a-b and a second backside metal 306 on a surface of a substrate 302. The substrate 302 may be a silicon wafer, and may include other materials (e.g., oxygen, nitrogen, various metals, etc.). The substrate may include cavities (used to form through substrate vias (TSVs) 308a-c). The first backside metals 304a-b and the second backside metals 306 may include copper, silver, gold, tungsten, or any other suitable metal and/or alloys thereof. The first backside metals 304a-b and the second backside metals 306 may be formed using chemical vapor deposition (CVD), electroplating, atomic layer deposition (ALD), sputtering, plasma enhanced CVD, and/or any other suitable technique. The first backside metals 304a-b may form at least a portion of a PDN for the device 300.

The second backside metal 306 may include the same metals as the first backside metals 304a-b and/or may include different metals. The second backside metal 306 may be formed at the same time as the first backside metals 304a-b and/or may be formed at a different time. The second backside metal 306 may be formed in a separate track (e.g., not in a contiguous line) from the first backside metals 304a-b or may be formed on the same channel. The second backside metal 306 may be electrically isolated from the first backside metals 304a-b. The second backside metal 306 may therefore be used to provide data signals within the device 300.

At step 204, the method 200 may include forming one or more vias (e.g., the TSVs 308a-c) within the one or more cavities. The one or more cavities may be filled with metal including copper, silver, gold, tungsten, or any other suitable metal and/or alloys thereof forming the TSVs 308a-c. The TSVs 308a-c may be formed using CVD, electroplating, ALD, sputtering, plasma enhanced CVD, and/or any other suitable technique. The TSVs 308a-c may be connected to the first backside metals 304a-b and/or the second backside metal 306. As shown in FIG. 3, the TSVs 308a-b may be connected to the first backside metals 304a-b and the TSV 308c may be connected to the second backside metal 306. Thus, a portion of the vias (e.g., the TSVs 308a-b) may be power vias while another portion of the vias (e.g., the TSV 308c) may be a data via. From a manufacturing standpoint, however, all of the TSVs 308a-c may be formed in a single process and be similar (or identical). In other words, the TSVs 308a-c (and the first and second backside metal layers) may formed as part of a PDN, but some portion may be later configured to carry data signals instead of power signals. The backside PDN may therefore be used to transmit both power and data signals.

At step 206, the method 200 may include forming a device layer 312 comprising at least a gate (e.g., active gates 314a-b) and a source/drain (e.g., a source 315), wherein the source/drain is in contact with at least one of the metal vias. As shown in FIG. 3, the TSV 308c may be connect to the source 315. The source 315 may be component of a device within the device layer 312 (e.g., a transistor). For example, the source 315 may be part of an active transistor within the device layer 312. A data signal (e.g., a clock signal, a reset signal, etc.) may be provided using the second backside metal 306 and the TSV 308c to the device layer 312. In another example, the source 315 may not be connected to an active device and/or may include a metal contact. The source 315 may therefore be thought of as a dummy source, used to enable the data signal to be transmitted/received using the second backside metal 306 and the TSV 308c.

The device layer 312 may also include dummy gates 316a-b. The dummy gates 316a-b may be formed of polysilicon, a metal-oxide(s) (including tungsten, aluminum, cobalt, titanium, nickel, and/or any other suitable metal and/or alloys thereof), and/or any other suitable material(s). The dummy gates 316a-b may at least partially isolate the data signal transmitted to the source 315 from other signals (e.g., power signals transmitted through the PDN, other data signals, etc.). The active gates 314a-b may be components of devices included in the device layer 312. For example, the active gates 314a-b may be transistors or other devices used during the operation of the device 300. Whereas the dummy gates 316a-b may not be connected to any active devices, the active gates 314a-b may serve as inputs for active devices within the device layer 312.

At step 208, the method 200 may include forming a second metal layer (e.g., a frontside metal layer 318) connecting the source 315 to the gate (e.g., the active gates 314a-b). The frontside metal layer 318 may be formed using CVD, electroplating, ALD, sputtering, plasma enhanced CVD, and/or any other suitable technique. The frontside metal layer 318 may be a metal pathway used to transmit data signals. In other words, the frontside metal layer 318 may be formed as part of a data network used to pass data signals to and from various devices within the device layer 312. As shown in FIG. 3, the frontside metal layer 318 may connect the source 315 to the active gates 314a-b. Therefore, a data signal may be provided to the source 315 using the second backside metal 306 and the TSV 308c. Then, the data signal may be provided to the active gates 314a-b using the frontside metal layer 318.

Although not shown in FIG. 3, the frontside metal layer 318 may be part of a larger data network, used to pass multiple signals to and from various devices within the device layer 312. Furthermore, the device 300 may include multiple device layers, each with their own sets of active devices. Not all devices (in the device layer 312 and/or other device layers) may need the same data signals, however. The frontside metal layer 318 may not be monolithic (as shown in FIG. 3), but instead include a network of metal pathways connecting devices to others, according to the function(s) of each device. As a result, the frontside metal layer 318 may be complex, requiring space in order to route data signals properly while maintaining signal integrity. However, some (if not all) of the devices within the device layer 312 and/or other device layers may utilize a specific data signal or set of data signals (e.g., a clock signal). The second backside metal 306, the TSV 308c, and source 315 may therefore be used to efficiently provide the specific signal to the required devices, while reducing the space needed on the frontside of the device 300.

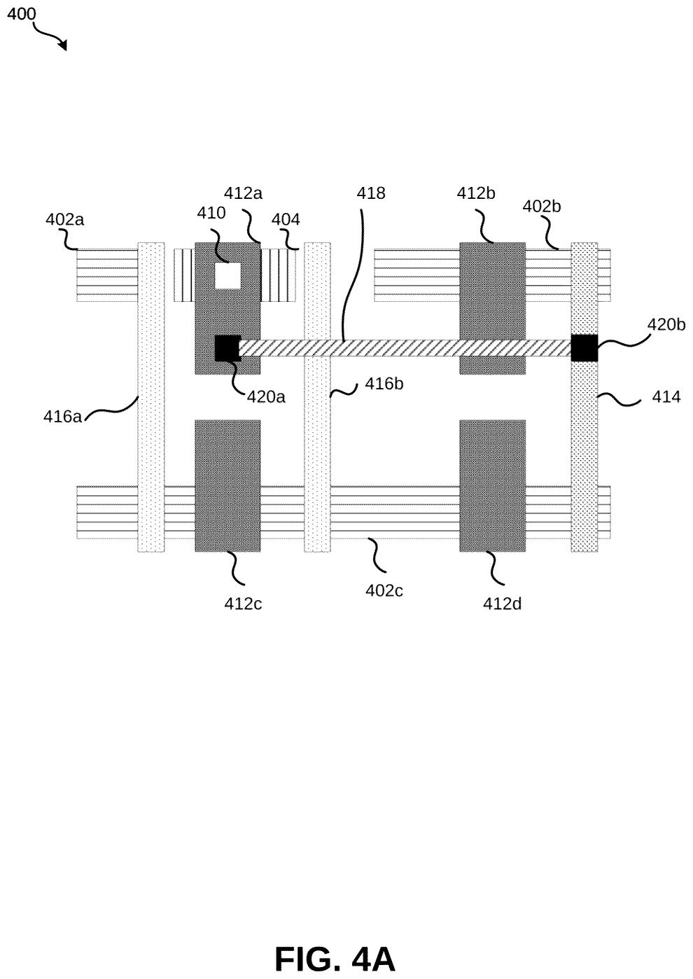

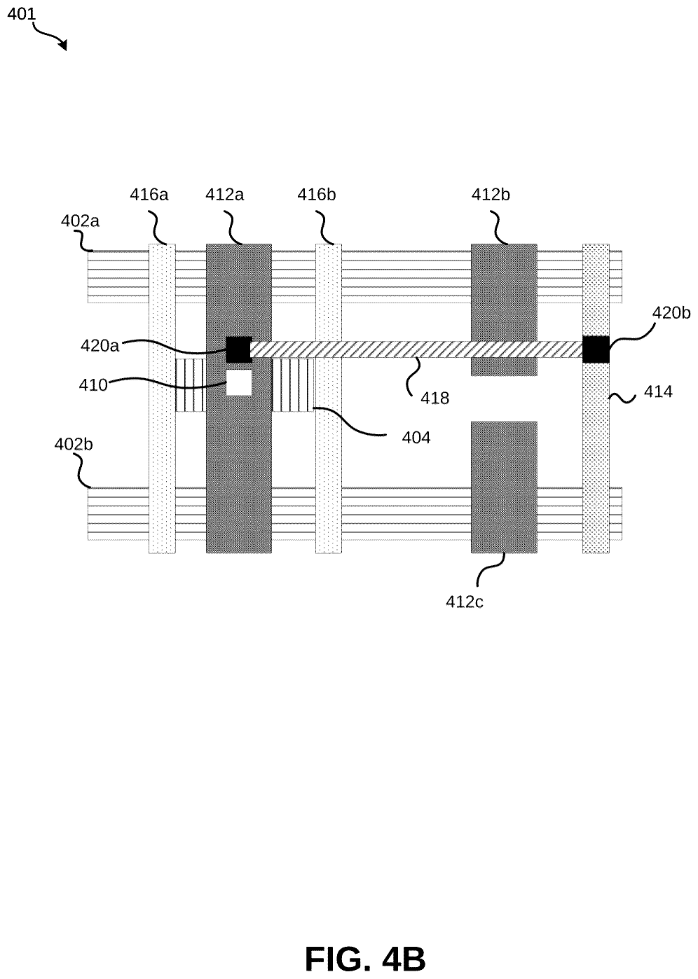

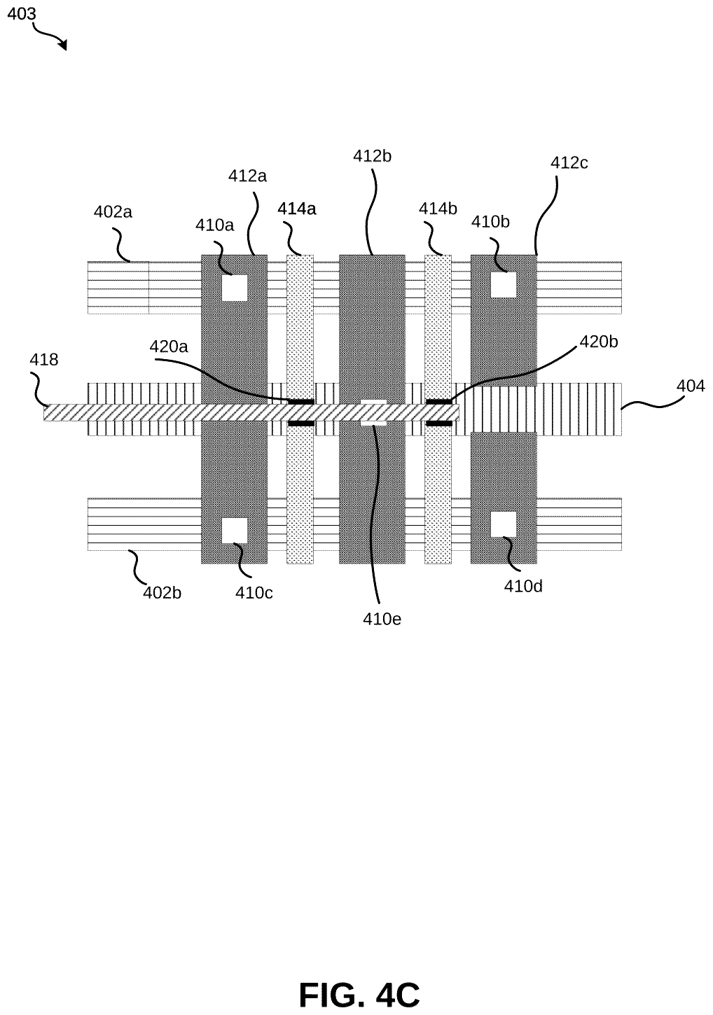

FIG. 4A illustrates a top-down view of a semiconductor device 400 with a backside signal channel, according to certain embodiments. The semiconductor device (“device”) 400 may be identical to the device 300, and/or may include different features and components. The device 400 may be formed using the method 200. The device 400 may include first backside metals 402a-c, a second backside metal 404, a TSV 410, sources 412a-d, an active gate 414, dummy gates 416a-b, a frontside metal 418, and contacts 420a-b. The device 400 may be formed on and/or around a substrate, such as the substrate 302 in FIG. 3. Thus, the substrate may be formed of silicon, gallium, arsenic, and/or any other suitable material or combination thereof. The first backside metal layers 402a-c may be similar to the first backside metal layers 304a-b in FIG. 3. The first backside metal layers 402a-c may include copper, silver, gold, tungsten, or any other suitable metal and/or alloys thereof. The first backside metal layers 402a-c may be formed may be formed using CVD, electroplating, ALD, sputtering, plasma enhanced CVD, and/or any other suitable technique. The first backside metal layers 402a-c may therefore form some or all of a backside PDN (BPDN).

The second backside metal layer 404 may be similar to the second backside metal layer 306 in FIG. 3. The second backside metal layer 404 may therefore also include copper, silver, gold, tungsten, or any other suitable metal and/or alloys thereof. The second backside metal layer 404 may be formed using CVD, electroplating, ALD, sputtering, plasma enhanced CVD, and/or any other suitable technique. The second backside metal layer 404 be used to provide data signals via a backside data channel. As shown in FIG. 4A, the second backside metal 404 may be formed in a contiguous line or track with some or all of the first backside metals 402a-c. For example, the first backside metals 402a-b may be formed in a line and the second backside metal 404 may be formed in the middle of the first backside metals 402a-b. The second backside metal 404 may be electrically isolated from the first backside metals 402a-c. If the first backside metals 402a-c are used as a PDN, therefore, the second backside metal 404 may be used to transmit a data signal without interference from the PDN (and vice versa).

The TSV 410 may be similar to the TSV 308c in FIG. 3. The TSV 410 may connect the second backside metal 404 to the source 412a. The source 412a may be connected to an active device in a device layer of the device 400 or may be a dummy source. For example, the sources 412b-d may be sources of active devices within the device layer. Thus, the sources 412b-d may be connected to the PDN (i.e., the first backside metals 402a-c). The source 412a, however, may not be connected to the PDN, instead connected to the second backside metal 404. Therefore, a data signal (e.g., a clock signal) may be routed from the backside of the device 400 to a frontside of the device 400.

The active gate 414 may be a poly gate, including polysilicon, a metal oxide(s) (including tungsten, aluminum, cobalt, titanium, nickel, and/or any other suitable metal and/or alloys thereof), and/or other suitable materials. The active gate 414 may be connected to one or more active devices (e.g., transistors) that utilize the signal provided using the second backside metal 404. The source 315 may be connected to the active gate 414 using the frontside metal 418 and the contacts 420a-b. The frontside metal 418 may include copper, silver, gold, tungsten, or any other suitable metal and/or alloys thereof and be formed using CVD, electroplating, ALD, sputtering, plasma enhanced CVD, and/or any other suitable technique. The contacts 420a-b may be polysilicon contacts, metal-semiconductor contacts, or any other suitable type of contact.

The frontside metal 418 may be part of a data network formed on the frontside of the device 400. However, the frontside metal 418 may be configured only to transmit data signals received via the second backside metal 404. The second backside metal 404, the TSV 410, the frontside metal 418, and the contacts 420a-c may therefore be considered a backside data channel, used to provide a data signal to one or more active devices within the device layer from the backside of the device 400.

Although only one active gate 414 is shown, it should be understood that any number of active gates (i.e., devices, transistors, etc.) may be present in the device 400. Some or all of the active gates may utilize the data signal provided by the backside data channel. The frontside metal 418 may then be used to connect the necessary active gates to the source 412a. By routing the data signal to the source 412a and connecting the necessary active gates via the frontside metal 418, space may be conserved in topside routing, allowing other components of the data network to be routed more efficiently. The device 400 may therefore be made more complex and/or compact as compared to current devices.

In some embodiments, the device 400 may additionally or alternatively transmit data signals from the frontside to the backside. For example, the source 412a may generate and/or transmit a data signal to be used by one or more other elements of the device layer. The data signal may be transmitted to the source via the frontside metal 418. Then, the data signal may be transmitted to the second backside metal 404 utilizing via the TSV 410. The data signal may then be transmitted to other elements of the device layer by the backside PDN (as described above).

FIG. 4B illustrates a top-down view of a semiconductor device 401 with a backside signal channel, according to certain embodiments. The device 401 may be similar to the device 400 in FIG. 4A but have a different configuration. As shown in FIG. 4B, the device 401 may include the first frontside metals 402a-b, the second backside metal 404, and sources 412a-c (as well as the other components, described in relation to FIG. 4A). The second backside metal 404 in FIG. 4B is shown in a separate track from the first backside metals 402a-b. The separation of the second backside metal 404 in a different track from the first backside metals 402a-b may improve the signal integrity of the data signal provided via the backside data channel.

Another benefit of the configuration shown in FIG. 4B may be an increased efficiency in routing the backside data channel to multiple devices. For example, in some applications, a short run (e.g., 10 microns, 12 microns, 14 microns, 20 microns, 30 microns, etc.) for the backside data signal may be desirable (e.g., a weak signal, particularly crucial signal, etc.). Then, the second backside metal 404 may extend along a full length of the device 401 and/or the track dedicated to the second backside metal 404. Multiple TSVs (similar to the TSV 410) may connect to multiple sources 412a (e.g., dummy sources) which in turn connect to multiple active gates (similar to the active gate 414) via the frontside metal 418 (or similar pathways). In other words, each run of the backside data channel from the backside to an active gate in then device layer may be shorter than current technologies (and/or over the configuration illustrated in FIG. 4A).

FIG. 4C illustrates a top-down view of a semiconductor device 403, according to certain embodiments. The device 403 may be similar to the devices 400 and 401 in FIGS. 4A-B, respectively. The device 403 may be used to provide high-drive signals by connecting a device to a low resistance signal track. Because backside networks (e.g., a BPDN) tend to have larger pathways, the resistance of the backside networks tend to be lower than those of data networks. Thus, the backside networks may be used to provide high-drive signals (e.g., inverter output) to devices within the device layer. In traditional technologies, this may require multiple TSVs to connect the devices to a lower resistance channel.

As seen in FIG. 4C, the sources 412a and 412c may be connected to first backside metals 402a-b using TSVs 410a-d (although not shown in previous figures, similar TSVs may be used to connect devices (i.e., the sources 412b-d) to the BPDN). Here, the second backside metal 404 may be a low resistance, high-drive power signal (e.g., an inverter output). The TSV 410c may connect the second backside metal 404 to the source 412b. Then, the high-drive signal may be connected to active gates 414a-b to provide the high drive power signal to active devices associated with the active gates 414a-b and/or the sources 412a and 412c via the frontside metal 418. Thus, the source 412b (along with the second backside metal 404 and the TSV 410c) may be thought of as a high-drive cell. The active gates 414a-b may then be connected to the high-drive cell in parallel. In current technologies, additional TSVs may be needed in order to connect the active devices to the high-drive signal. Thus, the device 402 may more efficiently deliver a high-drive signal to active devices, and/or may be more efficient to manufacture.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMS, EEPROMs, magnetic or optical cards, flash memory, or other types of machine-readable mediums suitable for storing electronic instructions. Alternatively, the methods may be performed by a combination of hardware and software.

What is claimed is:

1. A semiconductor device, comprising:
a backside power delivery network (BPDN) formed on a backside of a substrate, the BPDN comprising power signals and a data signal;
a device layer overlaying the BPDN, the device layer comprising a device with a gate; and
a frontside metal layer overlaying the device layer, wherein the data signal in the BPDN is conductively connected to the gate through the metal layer through one or more vias extending through the device layer.

2. The semiconductor device of claim 1, further comprising:
a dummy gate formed in the device layer and configured to isolate the data signal from the BPDN.

3. The semiconductor device of claim 1, wherein the data signal of the BPDN is connected to a source/drain formed in the device layer and the source/drain is connected to the gate via the metal layer.

4. The semiconductor device of claim 1, wherein the data signal is conductively connected to a plurality of gates of the device layer via the metal layer, characterized by a run distance of 10 to 20 microns, inclusive.

5. The semiconductor device of claim 1, wherein the power signal and the data signal are provided on a single track.

6. The semiconductor device of claim 1, wherein the power signal and the data signal are provided on separate tracks.

7. The semiconductor device of claim 1, wherein the data signal comprises a clock signal and/or a reset signal.

8. A method of forming a semiconductor device, comprising:
forming a first metal layer on a back side of a substrate, the substrate comprising a one or more cavities extending from a front side of the substrate to the back side of the substrate;
forming one or more metal vias within the one or more cavities;
forming a device layer comprising at least a gate and a source/drain, wherein the source/drain is in contact with at least one of the metal vias; and
forming a second metal layer connecting the source/drain to the gate.

9. The method of claim 8, wherein first metal layer and at least one of the one or more metal vias are a backside power delivery network (BPDN).

10. The method of claim 8, wherein the at least one metal via connected to the source/drain is configured to provide a data signal from at least one of the first metal layer to the second metal layer or the second metal layer to the first metal layer.

11. The method of claim 8, further comprising forming one or more dummy gates such that the metal via connected to the source/drain is isolated.

12. The method of claim 8, wherein the first metal layer comprises a single track configured to provide power signals and data signals.

13. The method of claim 8, wherein the first metal layer is formed using a chemical vapor deposition process.

14. The method of claim 8, wherein the device layer comprises a high drive cell comprising one or more gates conductively connected in parallel.

15. The method of claim 8, wherein a first portion of the one or more metal vias are power vias and a second portion of the one or more metal vias are data vias, and the first portion and the second portion are formed by a single process.

16. The method of claim 15, wherein the data vias form a portion of a route with a length between 10 and 20 microns, inclusive.

17. The method of claim 8, wherein the first metal layer is formed on a first track for providing power signals and a second track for providing data signals.

18. A semiconductor device, comprising:
a substrate;
a backside metal layer disposed on a backside of the substrate and comprising a first track and a second track;
a device layer comprising a dummy source, a dummy gate, an active source, and an active gate;
a frontside metal pathway electrically connecting the dummy gate and the active gate; and
a first metal through substrate via (TSV) connecting the first track and the active source; and
a second metal TSV connecting the second track and the dummy source.

19. The semiconductor device of claim 18, wherein the second track, the second metal TSV, and the frontside metal pathway form a backside data channel.

20. The semiconductor device of claim 18, wherein the first track and the first metal TSV form a power delivery network.
